(19) United States
(12) Patent Application Publication
(10) Pub. No.: US 2004/0095169 A1
(43) Pub. Date: May 20, 2004

(54) Clock generating circuit including memory for regulating delay amount of variable delay circuit in ring oscillator

(75) Inventor: Satoshi Kaneko, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/459,492

(22) Filed: Jun. 12, 2003

(30) Foreign Application Priority Data
Nov. 15, 2002 (JP) 2002-331858

(51) Int. Cl. H03B 19/00

(52) U.S. Cl. 327/119

(57) ABSTRACT

A rewritable memory (120) stores a plurality of regulation amounts (increase amounts and decrease amounts) related to values of signals (240b and 240c) (to give information about a difference amount between an oscillation frequency of a ring oscillator (110) and a desired frequency). A control circuit (131) selects one of the regulation amounts from the memory (120) corresponding to the values of the signals (240b and 240c) and increases or decreases a value of a counter (132) by the regulation amount thus selected. The oscillation frequency is regulated by the value of the counter (132).

### BACKGROUND OF THE INVENTION

1. Field of the Invention

The present invention relates to a clock generating circuit.

2. Description of the Background Art

In a conventional digital type PLL (Phase Locked Loop) circuit, a phase comparator compares a phase of an oscillation clock obtained by a ring oscillator with that of an input clock and controls a delay amount of the ring oscillator based on a result of the comparison. In detail, if the phase of the oscillation clock leads that of the input clock, that is, an oscillation frequency is higher than a desired frequency (a frequency which is multiplication ratio times as high as a frequency of the input clock), the phase comparator decreases a value of a counter for controlling the delay amount of the ring oscillator, that is, controlling the oscillation frequency. To the contrary, if the phase of the oscillation clock lags that of the input clock, that is, the oscillation frequency is lower than the desired frequency, the phase comparator increases the value of the counter. At this time, the phase comparator increases or decreases the value of the counter by a count value of “1” (which is fixed on a circuit (hardware) basis) in the conventional PLL circuit.

The digital PLL circuit has been introduced in the following documents, for example:

Japanese Patent Application Laid-Open No. 11-220365 (1999) gazette, Japanese Patent Application Laid-Open No. 8-316826 (1996) gazette, U.S. Pat. No. 6,225,840, U.S. Pat. No. 6,049,238, U.S. Pat. No. 6,157,226, U.S. Pat. No. 6,366,150, Michel Combes, Karim Dioury, and Alain Greiner, A Portable Clock Multiplier Generator Using Digital CMOS Standard Cells, “IEEE JOURNAL OF SOLID-STATE CIRCUITS, VOL.31, NO.7, JULY 1996”, pp. 958-965, and Koichi Ishimi, Katsunori Sawai, and Kazusada Shimizu, Development of Full Digital PLL for Reduction in Voltage, “Technical Report of The Institute of Electronics, Information and Communication Engineers, vol. 97, No. 106, pp. 29-36, 1997/6”.

In the conventional digital PLL circuit, the phase comparator increases or decreases the delay amount of the ring oscillator by the count value of “1”. Therefore, there is a problem in that a long time is taken for the oscillation frequency to reach a desired value, i.e., a long time (lock time) is taken for stabilizing an output clock. Moreover, a variation in a characteristic of a transistor tends to be increased with microfabrication of the transistor, there is a problem in that such a variation reduces a stability of the PLL circuit.

### SUMMARY OF THE INVENTION

In consideration of such a respect, it is an object of the present invention to provide a clock generating circuit in which a lock time is more shortened and stabilized than that in a conventional circuit.

The present invention is intended for a clock generating circuit for multiplying a frequency of an input clock to output a clock having a desired frequency. According to the present invention, the clock generating circuit includes a ring oscillator, a rewritable memory, a judging section and a delay control section. The ring oscillator is constituted by a loop including a variable delay circuit for digitally regulating a delay amount. The memory stores a plurality of regulation amounts for regulating the delay amount. The plurality of regulation amounts include at least one first regulation amount for decreasing the delay amount to increase an oscillation frequency of the ring oscillator, and at least one second regulation amount for increasing the delay amount to decrease the oscillation frequency. The judging section is constituted to judge a level of the oscillation frequency with respect to the desired frequency. The delay control section is constituted to select one of the regulation amounts in the memory based on a result of a judgment obtained by the judging section and to control the delay amount with the regulation amount thus selected so as to eliminate a difference between the oscillation frequency and the desired frequency.

Since the regulation amounts for regulating the delay amount are stored in the rewritable memory, the regulation amount to be used can easily be changed. Accordingly, the present invention can cope with various situations more flexibly (depending on a multiplication ratio, the difference amount between the oscillation frequency and the desired frequency or a variation in a characteristic of a transistor, for example) as compared with a conventional clock generating circuit for regulating the delay amount with a fixed value. In this case, a larger regulation amount than the conventional fixed value is stored in the memory so that a time (lock time) taken for the oscillation frequency to reach the desired frequency can be more shortened, i.e., a stable output can be obtained earlier than that in the conventional clock generating circuit.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram for explaining a clock generating circuit according to a first embodiment,

FIG. 2 is a block diagram for explaining a multiplying circuit according to the first embodiment,

FIG. 3 is a block diagram for explaining a pulse counter according to the first embodiment,

FIGS. 4 and 5 are typical diagrams for explaining an operation of the multiplying circuit according to the first embodiment,

FIG. 6 is a typical diagram for explaining an operation of a control circuit according to the first embodiment,

FIG. 7 is a block diagram for explaining a multiplying circuit according to a second embodiment,

FIG. 8 is a block diagram for explaining a pulse counter according to the second embodiment,

FIG. 9 is a typical diagram for explaining an operation of a control circuit according to the second embodiment,

FIG. 10 is a block diagram for explaining a multiplying circuit according to a third embodiment,

FIG. 11 is a typical diagram for explaining an operation of an external circuit according to the third embodiment,

FIG. 12 is a block diagram for explaining a clock generating system according to the third embodiment,

FIG. 13 is a block diagram for explaining a multiplying circuit according to a fourth embodiment,

FIG. 14 is a block diagram for explaining a pulse counter according to the fourth embodiment, and

FIG. 15 is a typical diagram for explaining an operation of an external circuit according to the fourth embodiment.

### DESCRIPTION OF THE PREFERRED EMBODIMENTS

First Embodiment

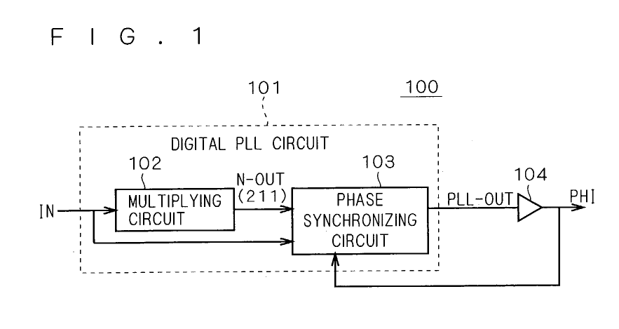

FIG. 1 is a block diagram for explaining a clock generating circuit 100 according to a first embodiment. The clock generating circuit 100 includes a digital type PLL (Phase Locked Loop) circuit 101, and a buffer 104. The PLL circuit 101 includes a multiplying circuit 102 and a phase synchronizing circuit 103.

The multiplying circuit 102 is constituted to generate a multiplication clock N-OUT (or 211) by multiplying a frequency of an input clock (or a reference clock) IN by a desired multiplication ratio N and to thus output the clock N-OUT. The phase synchronizing circuit 103 is constituted to delay the multiplication clock N-OUT in a certain delay amount (delay time) and to output a delayed clock as a PLL clock (or a PLL output clock) PLL-OUT. The PLL clock PLL-OUT is output as an output clock PHI of the clock generating circuit 100 through the buffer 104. The output clock PHI is supplied to another circuit to be operated synchronously therewith and is fed back to the phase synchronizing circuit 103. The phase synchronizing circuit 103 is constituted to compare a phase of the output clock PHI thus fed back with that of the input clock IN and to determine a delay amount of the output clock PLL-OUT with respect to the multiplication clock N-OUT so as to eliminate a difference between the phases.

Consequently, the clock generating circuit 100 generates and outputs the clock PHI which has a desired frequency obtained by multiplying the frequency of the input clock IN and is synchronous with the input clock IN. The multiplication processing is carried out by the multiplying circuit 102. Therefore, a circuit including at least the multiplying circuit 102 can be referred to as a “clock generating circuit” for outputting a clock having a desired frequency obtained by multiplying the frequency of the input clock IN. For example, only the multiplying circuit 102 can be referred to as the “clock generating circuit”, in this case, the output clock N-OUT sent from the multiplying circuit 102 is equivalent to an output clock of the “clock generating circuit”. Moreover, only the PLL circuit 101 can be referred to as the “clock generating circuit”, for example, in this case, the output clock PLL-OUT sent from the PLL circuit 101 is equivalent to the output clock of the “clock generating circuit”.

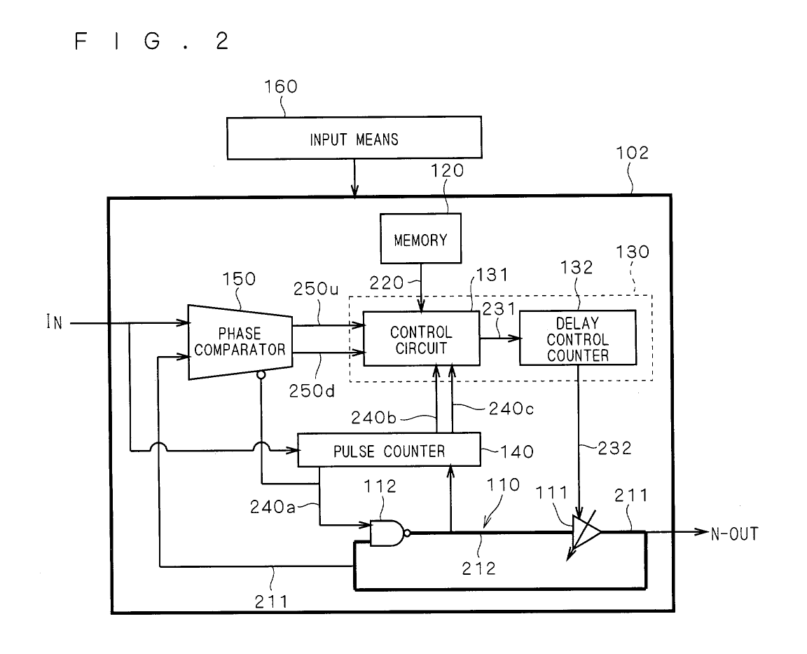

Next, the multiplying circuit 102 will be described in detail with reference to a block diagram of FIG. 2. As shown in FIG. 2, the multiplying circuit 102 includes a ring oscillator 110, a memory 120, a delay control section 130, a pulse counter 140 and a phase comparator (or a judging section) 150. Various values such as the multiplication ratio N are given to the multiplying circuit 102 through input means 160 such as a keyboard or a touch panel (including the case in which the values themselves are given and the case in which the values are included in a program for the multiplying circuit 102 and are thus given), and are stored in a memory which is not shown, for example, a register.

The ring oscillator 110 includes a digital delay line (or a variable delay circuit) 111 and a NAND circuit 112. An output of the NAND circuit 112 is connected to one of inputs of the NAND circuit 112 through the delay line 111. More specifically, the ring oscillator 110 is constituted by a loop (shown in a thick line for explanation) formed by the delay line 111 and the NAND circuit 112. In this case, the ring oscillator 110 is constituted as a negative feedback loop such that a level of a signal is inverted while the signal makes a round of the loop. Consequently, the ring oscillator 110 oscillates. The output signal (or oscillation clock) 211 sent from the delay line 111 is regulated to be multiplied by a multiplication ratio and is taken out as the multiplication clock N-OUT as will be described below.

The delay line 111 is a variable delay circuit constituted such that a delay amount can be regulated digitally (in other words, stepwise or discretely). More specifically, the delay line 111 includes a plurality of delay elements which can be cascade connected selectively and a delay amount thereof can be varied digitally in proportion to the number of the delay elements to be cascade connected. The delay line 111 has a positive polarity. By such a structure, the delay amount is variable in the ring oscillator 110 and a half of an oscillation cycle, that is, a half cycle of the ring oscillator 110 is coincident with a delay amount obtained while a signal makes a round.

The delay amount of the delay line 111 is controlled by the delay control section 130 including a control circuit 131 and a delay control counter 132. More specifically, the delay amount of the delay line 111 corresponds to a value set by the counter 132, and the delay line 111 is constituted such that the delay amount is set to be smaller if the value of the counter 132 is increased. If the delay amount is smaller, the oscillation cycle of the ring oscillator 110 is shortened, that is, the oscillation frequency is increased. More specifically, if the value of the counter 132 is increased, the oscillation frequency becomes higher. In other words, an increase or decrease in the value of the counter 132 corresponds to an increase or decrease in the oscillation frequency. The value of the counter 132 is controlled by a signal 231 sent from the control circuit 131 and is transmitted from the counter 132 to the delay line 111 with a signal 232. The delay control section 130 will be described below in detail.

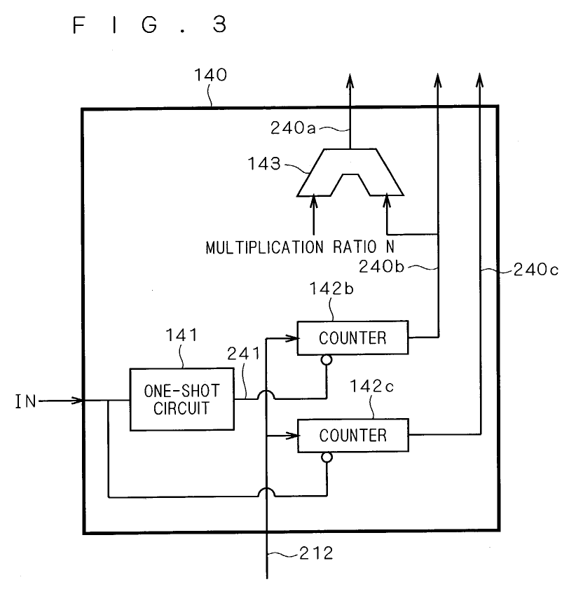

Next, the pulse counter 140 will be described with reference to a block diagram of FIG. 3. The pulse counter 140 includes a one-shot circuit 141, (first and second) counters 142b and 142c, and a comparator 143, and generates signals 240a, 240b and 240c by utilizing the input clock IN and an output signal (or oscillation clock) 212 of the NAND circuit 112 of the ring oscillator 110.

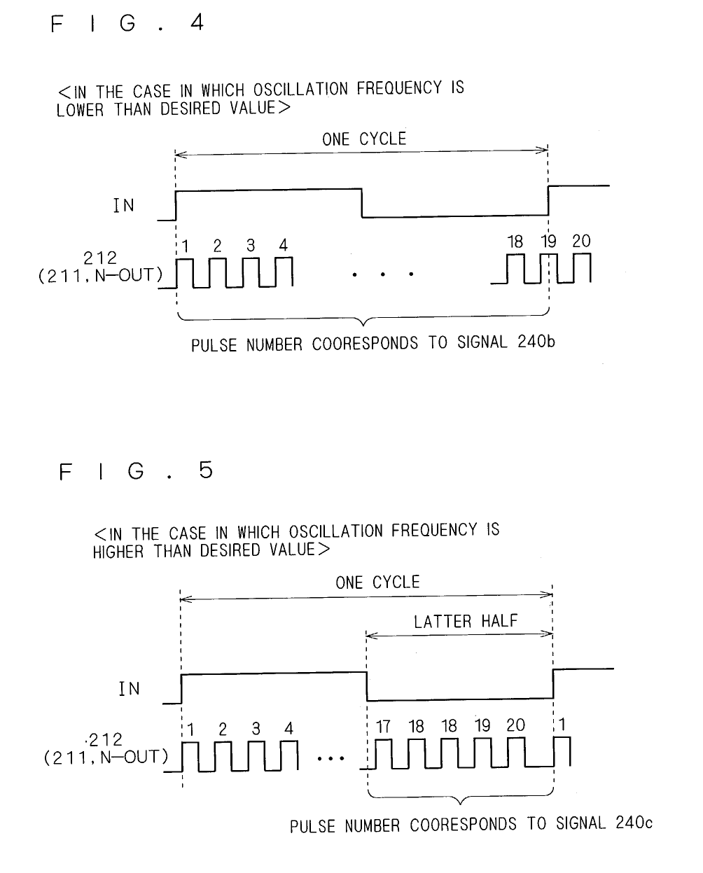

As shown in FIGS. 4 and 5 which will be described below, explanation will be given to the case in which one cycle of the input clock IN indicates a period between leading edges of pulses (the leading edge indicates a time of transition start from a Low level to a High level). For example, the multiplying circuit 102 can also be constituted in such a manner that a period between trailing edges of the pulses (the trailing edge indicates a time of transition start from the High level to the Low level) is set to be one cycle.

The one-shot circuit 141 is constituted to generate a one-shot signal 241 synchronously with a leading edge of the input clock IN. The one-shot signal 241 is a so called clock signal or impulse signal. The one-shot signal 241 is transmitted to the counter 142b.

The counter 142b is constituted to acquire the one-shot signal 241 and the oscillation clock 212, to be reset for each one-shot signal 241 and to count the number of pulses of the oscillation clock 212. More specifically, the counter 142b counts the number of pulses of the oscillation clock 212 of the ring oscillator 110 in one cycle of the input clock IN. Then, the counter 142b outputs a counted value with a signal 240b. As shown in FIGS. 2 and 3, the signal 240b is transmitted to the control circuit 131 and the comparator 143 in the multiplying circuit 102.

On the other hand, the counter 142c is constituted to acquire the input clock IN and the oscillation clock 212, to reset a count value for a period having the High level of the input clock IN and to count the number of pulses of the oscillation clock 212 for a period having the Low level of the input clock IN. More specifically, the counter 142c counts the number of the pulses of the oscillation clock 212 of the ring oscillator 110 in a latter half of one cycle of the input clock IN. Then, the counter 142c outputs a counted value with a signal 240c. As shown in FIGS. 2 and 3, the signal 240c is transmitted to the control circuit 131 in the multiplying circuit 102.

The signal (line) 240b is a group of a plurality of signals (lines) and is schematically shown with one signal (line) in FIG. 2 and the like, and so is the signal (line) 240c.

Moreover, the comparator 143 is constituted to acquire the output signal 240b transmitted from the counter 142b and the multiplication ratio N, and to output the signal 240a having the Low level if a value indicated by the signal 240b is coincident with the multiplication ratio N and to output the signal 240a having the High level in other cases. As shown in FIG. 2, the signal 240a is transmitted to the other input of the NAND circuit 112 of the ring oscillator 110 and the phase comparator 150.

In the case in which the NAND circuit 112 of the ring oscillator 110 acquires the signal 240a having the High level, the NAND circuit 112 inverts a level of the signal 211 fed back and outputs the signal 211 thus inverted and the oscillation of the ring oscillator 110 is continuously carried out. On the other hand, in the case in which the signal 240a has the Low level, the output of the NAND circuit 112 always has the High level irrespective of the signal 211 fed back. Therefore, the oscillation of the NAND circuit 112 is stopped.

Returning to FIG. 2, the phase comparator 150 is constituted to judge a level (level in frequency) of a frequency (oscillation frequency) of the oscillation clock 211 with respect to a desired frequency by utilizing the input clock IN, the output signal 211 of the delay line 111 and the signal 240a sent from the pulse counter 140. As a result of the judgment, the phase comparator 150 outputs a frequency-up signal or count-up signal 250u if the oscillation frequency is lower than the desired frequency, and outputs a frequency-down signal or count-down signal 250d if the oscillation frequency is higher than the desired frequency.

More specifically, in the case in which the signal 240a sent from the pulse counter 140 has the High level, the value indicated by the output signal 240b sent from the counter 142b, that is, the number of the pulses of the oscillation clock 212 does not reach the multiplication ratio N as described above. In other words, since the oscillation frequency is lower than the desired frequency, the phase comparator 150 outputs the frequency-up signal 250u as a result of the judgment for the level of the frequency.

On the other hand, in the case in which the signal 240a has the Low level, that is, the number of the pulses of the oscillation clock 212 is coincident with the multiplication ratio N, the phase comparator 150 compares a phase of the oscillation clock 211 with that of the input clock IN. The oscillation clock 211 to be input to the phase comparator 150 is delayed from the oscillation clock 212 for generating the signal 240a. Thereafter, the number of pulses of the oscillation clock 211 reaches the multiplication ratio N (an Nth pulse of the oscillation clock 211 is shifted in level) after the signal 240a is set to have the Low level. For this reason, if the phase of the oscillation clock 211 after the signal 240a is set to have the Low level (that is, a phase of the Nth pulse of the oscillation clock 211) leads that of the input clock IN, the oscillation frequency is higher than the desired frequency. Therefore, the phase comparator 150 outputs the frequency-down signal 250d as a result of the judgment for the level of the frequency. To the contrary, if the phase of the oscillation clock 211 lags that of the input clock IN, the oscillation frequency is lower than the desired frequency. Therefore, the phase comparator 150 outputs the frequency-up signal 250u as a result of the judgment for the level of the frequency. These signals 250u and 250d are sent to the control circuit 131.

The control circuit 131 increases the value of the delay control counter 132 by the signal 231 upon receipt of the frequency-up signal 250u, and decreases the value of the counter 132 by the signal 231 upon receipt of the frequency-down signal 250d. In the case in which the phases of the clocks IN and 211, that is, the frequencies thereof are coincident with each other (in this case, both of the signals 250u and 250d have the Low level, for example), the control circuit 131 neither increases nor decreases the value of the counter 132. Consequently, the value of the counter 132 is maintained to be constant.

At this time, the control circuit 131 particularly controls the value of the delay control counter 132 based on the signals 240b and 240c received from the pulse counter 140. With reference to typical diagrams of FIGS. 4 to 6, such control will be described by taking, as an example, the case in which a multiplication ratio of N=20 is set.

First of all, in the case in which the frequency of the oscillation clock 212 (or 211, N-OUT) is lower than a desired value as shown in FIG. 4, the number of the pulses of the oscillation clock 212 in one cycle of the input clock IN is smaller than the multiplication ratio 20, that is, 18 in the example of FIG. 4. On the other hand, in the case in which the oscillation frequency is higher than the desired value as shown in FIG. 5, the number of the pulses of the oscillation clock 212 in a latter half of the input clock IN is smaller than 10 to be a half of the multiplication ratio N, that is, 5 in the example of FIG. 5. In this case, a difference amount between each of the numbers of pulses in one cycle and the latter half of the input clock IN and the multiplication ratio N is equivalent to a difference amount between the oscillation frequency and the desired frequency. Accordingly, it is apparent that the number of pulses, that is, each of the values of the corresponding signals 240b and 240c provides information about the difference amount between the oscillation frequency and the desired frequency.

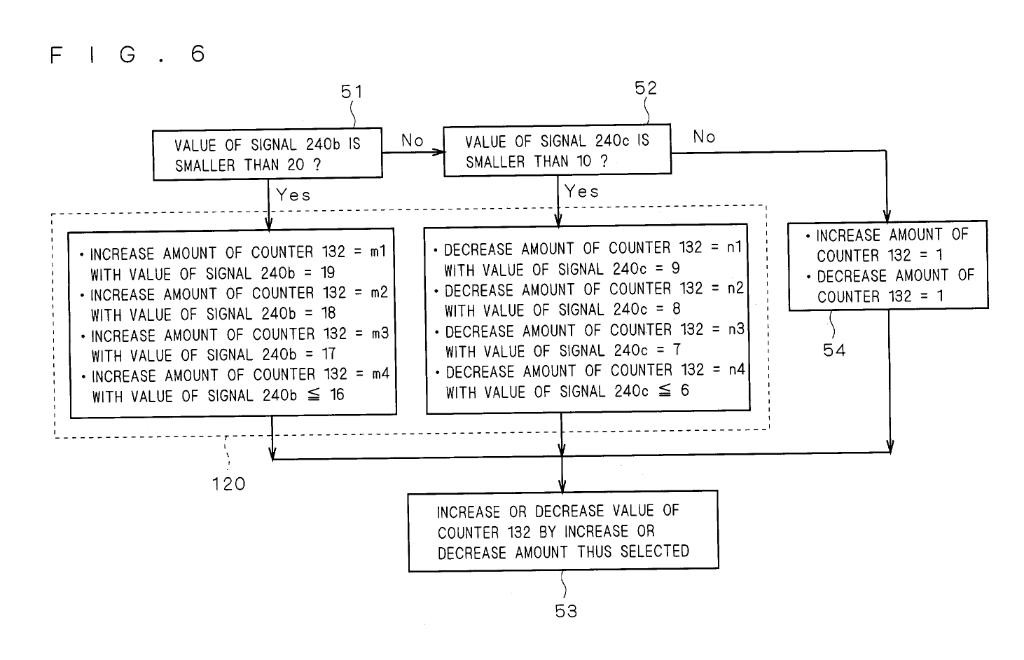

In consideration of such a respect, the control circuit 131 carries out a processing shown in FIG. 6. More specifically, the control circuit 131 first compares the value of the signal 240b with the multiplication ratio of N=20 (processing 51). As a result of the comparison, if the value of the signal 240b is smaller, the control circuit 131 selects an increase amount of the delay control counter 132 (or a first regulation amount) with reference to data or information in the memory 120 and increases the value of the counter 132 by the increase amount thus selected (processing 53). In particular, four increase amounts m1, m2, m3 and m4 (1<m1<m2<m3<m4, for example, m1=2, m2=3, m3=4 and m4=5) are stored in the memory 120 in relation to the value of the signal 240b as information about the difference amount between the oscillation frequency and the desired frequency. If the value of the signal 240b is decreased, that is, the difference amount between the oscillation frequency and the desired frequency is increased, a larger increase amount is prepared. The control circuit 131 selects the increase amount m1, m2, m3 or m4 corresponding to the value of the signal 240b.

In the case in which the signal 240b is not smaller than the multiplication ratio of N=20 as a result of the comparison processing 51, the control circuit 131 subsequently compares the value of the signal 240c with 10 to be a half of the multiplication ratio of N=20 (processing 52). As a result of the comparison, if the value of the signal 240c is smaller, the control circuit 131 selects a decrease amount of the delay control counter 132 (or a second regulation amount) with reference to data or information in the memory 120 and decreases the value of the counter 132 by the decrease amount thus selected (processing 53). In the same manner as the increase amounts m1, m2, m3 and m4, four decrease amounts n1, n2, n3 and n4 (1<n1<n2<n3<n4, for example, n1=2, n2=3, n3=4 and n4=5) are stored in the memory 120 in relation to the value of the signal 240c as information about the difference amount between the oscillation frequency and the desired frequency. If the value of the signal 240c is decreased, that is, the difference amount between the oscillation frequency and the desired frequency is increased, a larger decrease amount is prepared. The control circuit 131 selects the increase amount n1, n2, n3 or n4 corresponding to the value of the signal 240c.

In the case in which the signal 240c is not smaller than N/2=10 as a result of the comparison processing 52, moreover, the control circuit 131 increases or decreases the value of the counter 132 by 1 (processing 54).

The processings 51 and 52 may be executed in any order.

The delay amount of the delay line 111 is regulated (decreased or increased) with an updated counter value of the delay control counter 132, and as a result the oscillation frequency of the ring oscillator 110 is regulated (increased or decreased). In other words, the four increase amounts m1, m2, m3 and m4 are the (first) regulation amounts for decreasing the delay amount of the delay line 111 to increase the oscillation frequency of the ring oscillator 110, and the four decrease amounts n1, n2, n3 and n4 are the (second) regulation amounts for increasing the delay amount of the delay line 111 to decrease the oscillation frequency of the ring oscillator 110. Consequently, the multiplying circuit 102 is turned to eliminate the difference between the oscillation frequency and the desired frequency.

By using a microcomputer for the control circuit 131, for example, it is possible to implement the above-mentioned operation by a program. Moreover, the memory 120 is constituted by a rewritable memory, for example a register such as a flip-flop, a DRAM (Dynamic Random Access Memory) or a flash memory. Therefore, the increase amounts m1, m2, m3 and m4 and the decrease amounts n1, n2, n3 and n4 which are stored in the memory 120 can be changed through the input means 160 or the program of the control circuit 131, for example. The multiplying circuit 102 may be constituted to store, in the memory 120, the increase or decrease amount of “1” in the processing 54.

While the delay amount of the ring oscillator is increased or decreased by the count value of “1” in the conventional PLL circuit described above, the increase amounts m1, m2, m3 and m4 and the decrease amounts n1, n2, n3 and n4 which are greater than “1” can be utilized in the multiplying circuit 102. Therefore, a time (a lock time) taken for the oscillation frequency to reach the desired frequency can be reduced to be shorter, that is, a stable output can be obtained earlier than that in the conventional circuit. In addition, when the difference amount between the oscillation frequency and the desired frequency is great, the large increase or decrease amount is used so that the difference amount can be decreased quickly. When the difference amount is small, the small increase or decrease amount is used so that regulation can be carried out finely. In other words, the reduction in the lock time and the stability of the output are compatible with each other in the multiplying circuit 102.

Moreover, the regulation amounts m1, m2, m3, m4, n1, n2, n3 and n4 for regulating the delay amount of the delay line 111 are stored in the rewritable memory 120. Therefore, these values can easily be changed. Accordingly, it is possible to more flexibly cope with various situations, for example, the multiplication ratio as compared with the conventional circuit for regulating the delay amount with the fixed count value of “1”. A characteristic of a transistor is varied due to a variation in a manufacturing process and the variation in the characteristic tends to be increased with microfabrication of the transistor. Also in such a case, for example, it is possible to take countermeasures so as not to depend on the variation in the manufacturing process by setting the regulation amounts m1, m2, m3, m4, n1, n2, n3 and n4 based on a transistor characteristic in a semiconductor chip or a semiconductor device which has a test circuit for measuring the transistor characteristic. In other words, the stability can be enhanced.

It is apparent that the PLL circuit 101 and the clock generating circuit 100 each including the multiplying circuit 102 can also produce the same advantages.

The numbers of the increase and decrease amounts are not restricted to the example described above.

Moreover, FIGS. 4 and 5 show the case in which a duty factor of the input clock IN, that is, a ratio of a High level period to one cycle is 50%. The duty factor is not restricted to this value. For example, in the case in which the duty factor is 25%, the counter 142c counts the number of pulses of the oscillation clock in a residual ¾ cycle obtained by excluding a ¼ cycle from a cycle starting point in one cycle (that is, after the ¼ cycle passes since the cycle starting point). At this time, it is possible to judge that the oscillation frequency is higher than the desired frequency if the number of the pulses in the residual ¾ cycle is smaller than 15 (=a multiplication ratio of 20×¾).

Second Embodiment

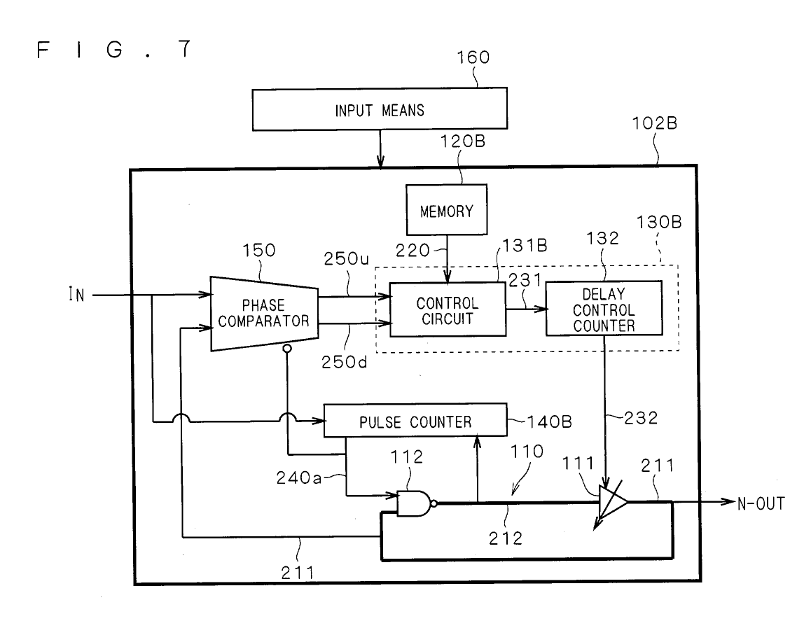

FIG. 7 is a block diagram for explaining a multiplying circuit 102B according to a second embodiment. The multiplying circuit 102B can be applied to the clock generating circuit 100 in place of the multiplying circuit 102 (see FIG. 1.)

The multiplying circuit 102B has such a structure that the memory 120, the delay control section 130 and the pulse counter 140 in the multiplying circuit 102 of FIG. 2 are replaced with a memory 120B, a delay control section 130B and a pulse counter 140B. Other structures of the multiplying circuit 102B are basically identical to those of the multiplying circuit 102 in FIG. 2.

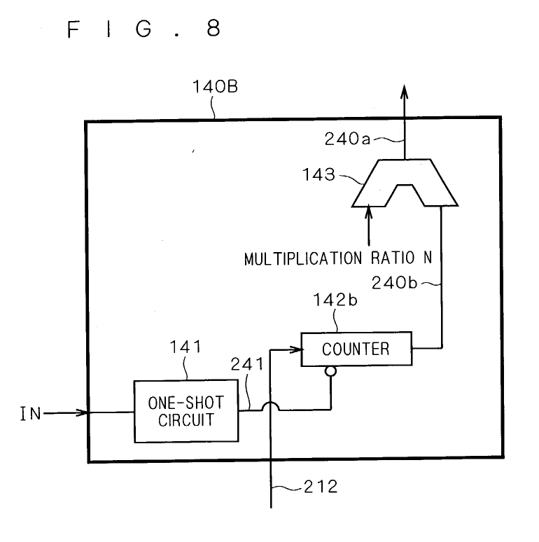

In detail, the pulse counter 140B has such a structure that the counter 142c is removed from the pulse counter 140 in FIG. 3 and is constituted to output only a signal 240a sent from a comparator 143 as shown in a block diagram of FIG. 8. More specifically, a signal is not sent from the pulse counter 140B to the delay control section 130B in the multiplying circuit 102B of FIG. 7 differently from the multiplying circuit 102 of FIG. 2. For this reason, a control circuit 131B of the delay control section 130B carries out a different operation from that of the control circuit 131 in FIG. 2 as will be described below. The delay control section 130B includes the delay control counter 132 in FIG. 2.

The memory 120B is rewritable in the same manner as the memory 120 in FIG. 2, and particularly, one increase amount m and one decrease amount n are stored in the memory 120B. Values of the increase amount m and the decrease amount n in the memory 120B can be changed through input means 160 or a program of the control circuit 131B, for example.

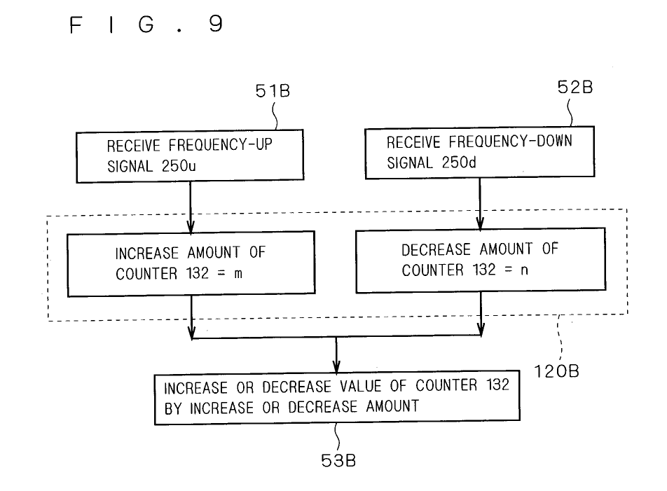

As shown in a typical diagram of FIG. 9, when receiving a frequency-up signal 250u from a phase comparator 150 (processing 51B), the control circuit 131B acquires the increase amount m with reference to data in the memory 120B and increases a value of the counter 132 by the increase amount m (processing 53B). On the other hand, when receiving a frequency-down signal 250d from the phase comparator 150 (processing 52B), the control circuit 131B acquires the decrease amount n with reference to the data in the memory 120B and decreases the value of the counter 132 by the decrease amount n (processing 53B). The processings 51B and 52B may be executed in any order.

According to the multiplying circuit 102B, the regulation amounts m and n are stored in the rewritable memory 120B. Therefore, these values can easily be changed. Accordingly, the multiplying circuit 102B can flexibly cope with various situations in the same manner as the multiplying circuit 102. It is apparent that the PLL circuit 101 and the clock generating circuit 100 each including the multiplying circuit 102B can also produce the same advantages.

Third Embodiment

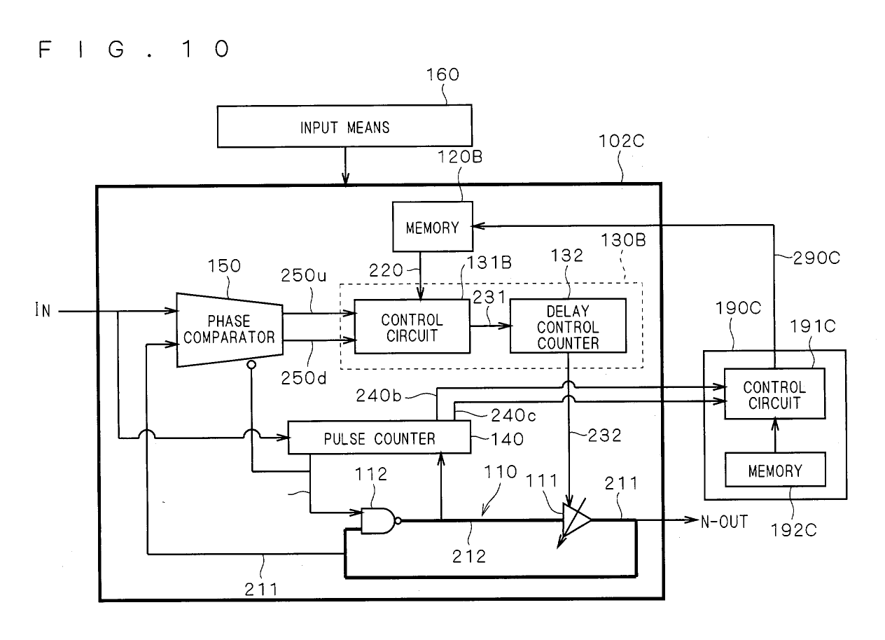

FIG. 10 is a block diagram for explaining a multiplying circuit 102C according to a third embodiment. The multiplying circuit 102C has such a structure that the pulse counter 140B of the multiplying circuit 102B in FIG. 7 is replaced with the pulse counter 140 in FIG. 2. Furthermore, the multiplying circuit 102C is constituted such that signals 240b and 240c (which provide information about the difference amount between the oscillation frequency and the desired frequency as described above) sent from the pulse counter 140 are output to an external circuit 190C and the external circuit 190C can access a memory 120B. Other structures of the multiplying circuit 102C are basically identical to those of the multiplying circuit 102B in FIG. 7.

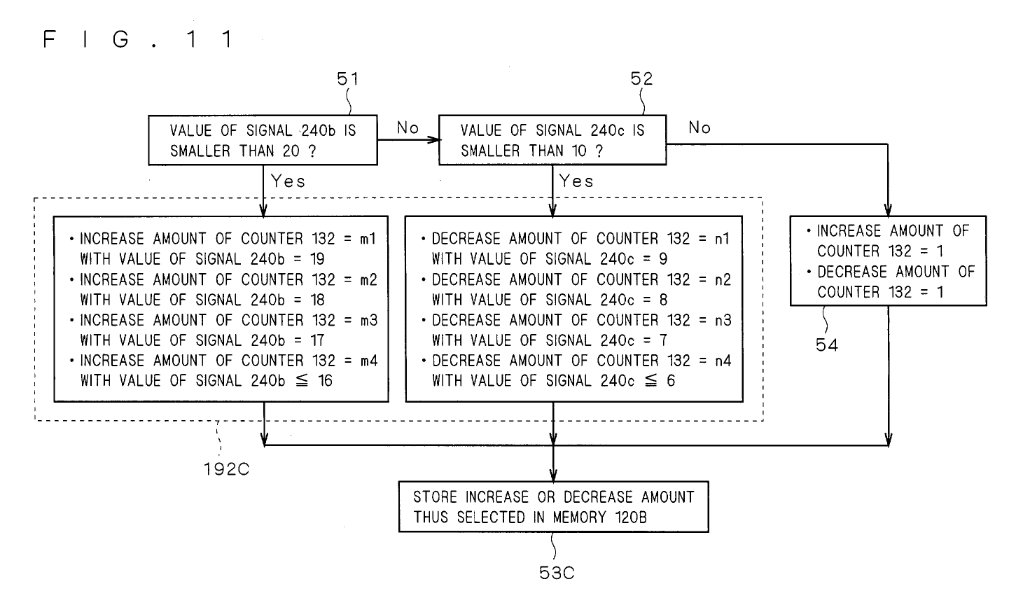

The external circuit 190C includes a control circuit 191C and a memory 192C and executes a processing shown in a typical diagram of FIG. 11 upon receipt of the signals 240b and 240c. Herein, the case in which a multiplication ratio of N=20 is set will be taken as an example.

As shown in FIG. 11, the same data as those in the memory 120 (see FIGS. 2 and 6) are stored in the memory 192C. The control circuit 191C is constituted to receive the signals 240b and 240c from the pulse counter 140, to execute the same processings 51, 52 and 54 as those of the multiplying circuit 102 in FIG. 2 and to select one increase amount m1, m2, m3 or m4 or one decrease amount n1, n2, n3 or n4. Then, the control circuit 191C stores (or rewrites) the increase or decrease amount thus selected in the memory 120B of the multiplying circuit 102C with a signal 290C. Consequently, the increase amount m or the decrease amount n in the memory 120B is updated (processing 53C).

The memory 192C of the external circuit 190C can be constituted by a rewritable memory, in this case the regulation amounts m1, m2, m3, m4, n1, n2, n3 and n4 in the memory 192C can be rewritten through input means 160 or input means which is not shown.

Then, a control circuit 131B of the multiplying circuit 102C executes the processing of FIG. 9 with reference to the data in the memory 120B.

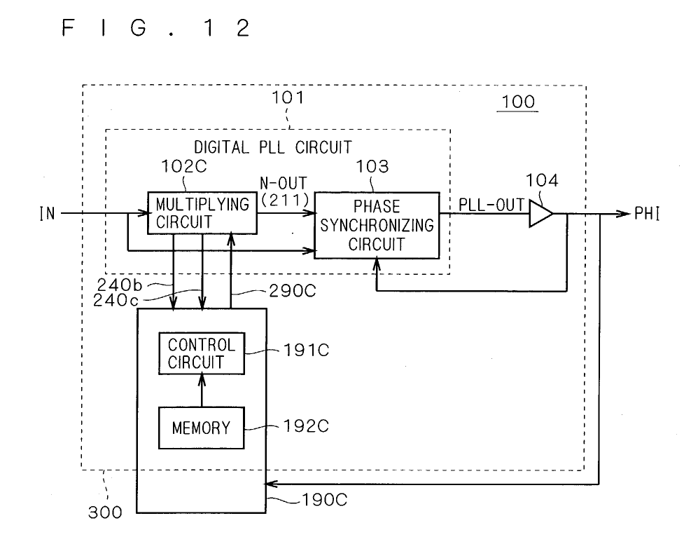

The multiplying circuit 102C can be applied to the clock generating circuit 100 in place of the multiplying circuit 102 (see FIGS. 1 and 12). In this case, as shown in a block diagram of FIG. 12, it is possible to utilize, as the external circuit 190C, a circuit provided on the outside of the clock generating circuit 100 and serving to receive an output clock PHI, for example. In such a case, a structure including the clock generating circuit 100 to which the multiplying circuit 102C is applied and the control circuit 191C and the memory 192C in the external circuit 190C will be referred to as a clock generating system 300.

By the multiplying circuit 102C, similarly, it is possible to produce the same advantages as those of the multiplying circuits 102 and 102B described above. In this case, precisely because the memory 120B is a rewritable memory, the external control circuit 191C can flexibly carry out rewriting corresponding to a difference amount between an oscillation frequency and a desired frequency.

Furthermore, since the multiplying circuit 102C has such a structure that a part of the processing in the multiplying circuit 102 of FIG. 2 is allotted for the external control circuit 191C, a circuit scale is smaller than that of the multiplying circuit 102 and is therefore small-sized.

It is apparent that the PLL circuit 101 and the clock generating circuit 100 each including the multiplying circuit 102C can also produce the same advantages.

Fourth Embodiment

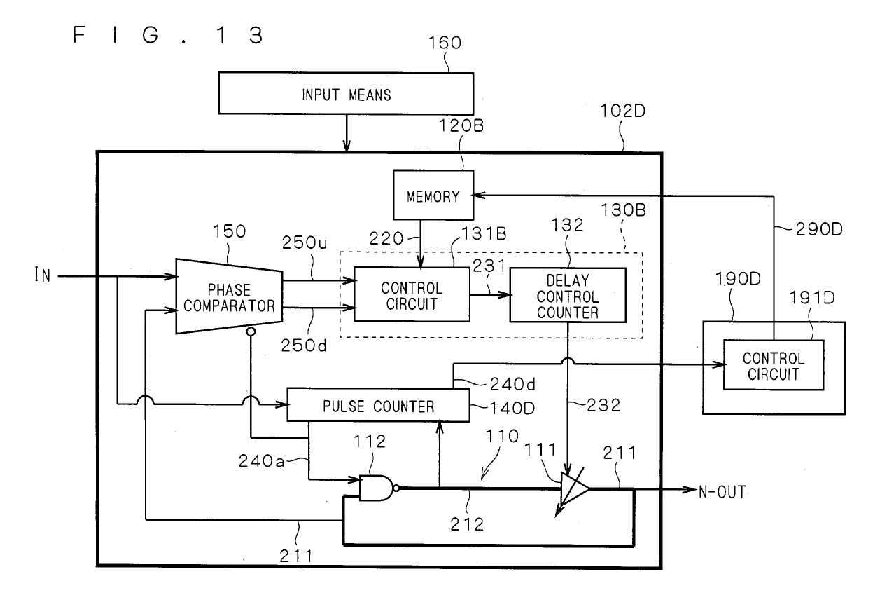

FIG. 13 is a block diagram for explaining a multiplying circuit 102D according to a fourth embodiment. The multiplying circuit 102D has such a structure that the pulse counter 140B of the multiplying circuit 102B in FIG. 7 is replaced with a pulse counter 140D. Furthermore, the multiplying circuit 102D is constituted such that a signal 240d is output from the pulse counter 140D to an external circuit 190D and the external circuit 190D can access a memory 120B. Other structures of the multiplying circuit 102D are basically identical to those of the multiplying circuit 102B in FIG. 7.

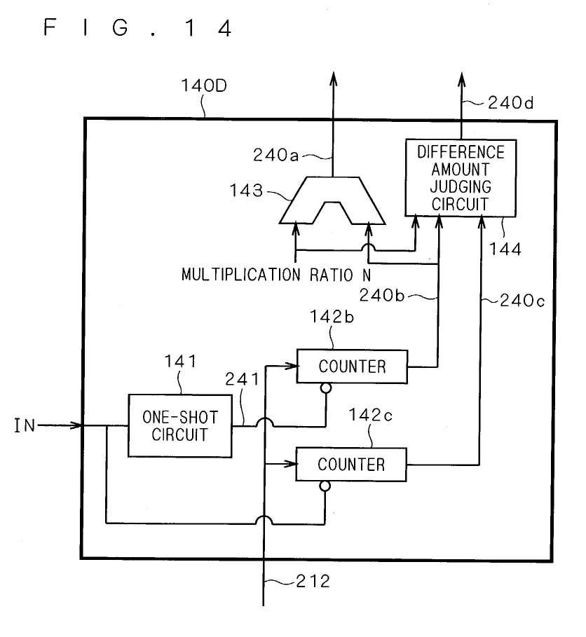

As shown in a block diagram of FIG. 14, the pulse counter 140D has such a structure that a difference amount judging circuit 144 is added to the pulse counter 140 of FIG. 3. The difference amount judging circuit 144 is constituted to utilize signals 240b and 240c sent from counters 142b and 142c and a multiplication ratio N, thereby outputting the signal 240d if a difference amount between an oscillation frequency and a desired frequency is equal to or greater than a predetermined value. For instance, in an example in which a multiplication ratio of N=20 is set, if a value of the signal 240b sent from the counter 142b is equal to or smaller than 16, the difference amount judging circuit 144 outputs, with the signal 240d, information indicating that the oscillation frequency is lower than the desired frequency. Similarly, the difference amount judging circuit 144 outputs, with the signal 240d, information indicating that the oscillation frequency is higher than the desired frequency if a value of the signal 240c sent from the counter 142c is equal to or smaller than 6.

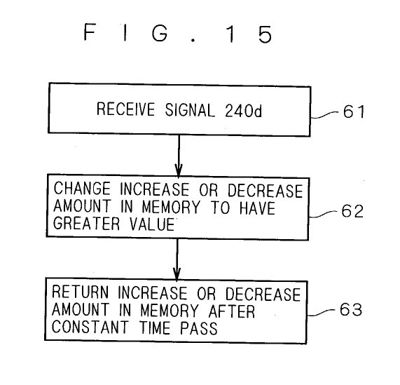

The external circuit 190D includes a control circuit 191D and executes a processing shown in a typical diagram of FIG. 15. More specifically, when receiving the signal 240d indicating that the oscillation frequency is lower than the desired frequency (processing 61), the control circuit 191D rewrites an increase amount m in the memory 120B of the multiplying circuit 102D to have a greater value with a signal 290D (processing 62). Then, the control circuit 191D returns the increase amount m into a value prior to change or an initial value with the signal 290D after a constant time passes (processing 63). Also in the case in which the signal 240d indicates that the oscillation frequency is higher than the desired frequency, the control circuit 191D carries out the same operation.

A control circuit 131B of the multiplying circuit 102D executes the processing of FIG. 9 with reference to data in the memory 120B.

The multiplying circuit 102D can be applied to the clock generating circuit 100 in place of the multiplying circuit 102 (see FIG. 1). Moreover, the multiplying circuit 102D and the external circuit 190D can also be applied to the clock generating system 300 in place of the multiplying circuit 102C and the external circuit 190C (see FIG. 12).

According to the multiplying circuit 102D, it is possible to produce the same advantages as those of the multiplying circuit 102C described above. Moreover, the PLL circuit 101 and the clock generating circuit 100 each including the multiplying circuit 102C can also produce the same advantages.

While the invention has been shown and described in detail, the foregoing description is in all aspects illustrative and not restrictive. It is therefore understood that numerous modifications and variations can be devised without departing from the scope of the invention.

What is claimed is:

1. A clock generating circuit for multiplying a frequency of an input clock to output a clock having a desired frequency, comprising:
a ring oscillator constituted by a loop including a variable delay circuit for digitally regulating a delay amount; and
a rewritable memory for storing a plurality of regulation amounts to regulate said delay amount,
wherein said plurality of regulation amounts include:
at least one first regulation amount for decreasing said delay amount to increase an oscillation frequency of said ring oscillator; and
at least one second regulation amount for increasing said delay amount to decrease said oscillation frequency,
said clock generating circuit further comprising:
a judging section constituted to judge a level of said oscillation frequency with respect to said desired frequency; and
a delay control section constituted to select one of said plurality of regulation amounts in said memory based on a result of a judgment obtained by said judging section and to control said delay amount so as to eliminate a difference between said oscillation frequency and said desired frequency by using a selected regulation amount.

2. The clock generating circuit according to claim 1, wherein
said at least one first regulation amount includes a plurality of first regulation amounts related to information about a difference amount between said oscillation frequency and said desired frequency,
said at least one second regulation amount includes a plurality of second regulation amounts related to said information about said difference amount, and
said delay control section is constituted to select one of said plurality of regulation amounts corresponding to said information about said difference amount.

3. The clock generating circuit according to claim 1, wherein
said at least one first regulation amount is one first regulation amount, and
said at least one second regulation amount is one second regulation amount,
said clock generating circuit being constituted to output information about a difference amount between said oscillation frequency and said desired frequency to an external control circuit and being constituted to allow said external control circuit to rewrite said one first regulation amount or said one second regulation amount in said memory based on said information about said difference amount.

4. The clock generating circuit according to claim 2, further comprising:
a first counter for counting the number of pulses of an oscillation clock of said ring oscillator in one cycle of said input clock; and
a second counter for counting said number of pulses of said oscillation clock for a residual period obtained by excluding a predetermined period from a cycle starting point in said one cycle of said input clock,
wherein said information about said difference amount includes count values obtained by said first and second counters.

5. The clock generating circuit according to claim 3, further comprising:
a first counter for counting the number of pulses of an oscillation clock of said ring oscillator in one cycle of said input clock; and
a second counter for counting said number of pulses of said oscillation clock for a residual period obtained by excluding a predetermined period from a cycle starting point in said one cycle of said input clock,
wherein said information about said difference amount includes count values obtained by said first and second counters.

6. The clock generating circuit according to claim 1, further comprising:
a first counter for counting the number of pulses of an oscillation clock of said ring oscillator in one cycle of said input clock;
a second counter for counting said number of pulses of said oscillation clock for a residual period obtained by excluding a predetermined period from a cycle starting point in said one cycle of said input clock; and
a difference amount judging circuit constituted to acquire said difference amount between said oscillation frequency and said desired frequency by using count values obtained by said first and second counters and a multiplication ratio and to output a signal if said difference amount is equal to or greater than a predetermined value, wherein
said at least one first regulation amount is one first regulation amount, and
said at least one second regulation amount is one second regulation amount,
said clock generating circuit being constituted to output said signal from said difference amount judging circuit to an external control circuit and being constituted to allow said external control circuit to rewrite said one first regulation amount or said one second regulation amount in said memory upon receipt of said signal.
